(19) United States
(12) Patent Application Publication
(10) Pub. No.: US 2018/0035529 A1
(43) Pub. Date: Feb. 1, 2018

(54) STRUCTURE HAVING METAL MATERIAL FOR HEAT RADIATION, PRINTED CIRCUIT BOARD, ELECTRONIC APPARATUS, AND METAL MATERIAL FOR HEAT RADIATION

(71) Applicant: JX NIPPON MINING & METALS CORPORATION, Tokyo (JP)

(72) Inventors: HIDETA ARAI, IBARAKI (JP); ATSUSHI MIKI, IBARAKI (JP); SATORU MORIOKA, TOKYO (JP)

(21) Appl. No.: 15/657,381

(22) Filed: Jul. 24, 2017

(30) Foreign Application Priority Data
Jul. 27, 2016 (JP) 2016-146866

(51) Int. Cl. H05K 1/02; F28F 21/08; F28F 3/08; F28F 21/02

(52) U.S. Cl. CPC H05K 1/0203; F28F 21/02; F28F 21/081; F28F 3/08

(57) ABSTRACT

A structure having a metal material for heat radiation that is capable of favorably radiating heat from a heat generating component is provided. A structure having a metal material for heat radiation, containing a heat generating component and a heat radiating member for radiating heat from the heat generating component, wherein the heat radiating member has a layer structure containing a metal material for heat radiation and a graphite sheet.

In the present application, priority is claimed based on Japanese Patent Application No. 2016-146866 filed on Jul. 27, 2016, and the entire disclosure of the Japanese Patent Application is incorporated herein by reference.

### Technical Field

The present invention relates to a structure having a metal material for heat radiation, a printed circuit board, an electronic apparatus, and a metal material for heat radiation.

### Background Art

Associated with the miniaturization and high definition of electronic apparatuses in recent years, there are problems including malfunctions and the like due to the heat generation of the electronic component used therein.

In view of the problems, for example, PTL 1 describes the research and development of the technique, in which a graphite sheet, which is a heat radiating member having a high thermal conductivity in the in-plane direction, is closely attached to the heat generating component directly or through an adhesive layer.

### CITATION LIST

### Patent Literature

PTL 1: JP-A-2013-021357

### SUMMARY OF INVENTION

### Technical Problem

The graphite sheet is effective as a heat radiating member, but there is still room for development in a structure of a heat radiating member capable of favorably radiating heat from a heat generating component, other than the structure constituted only by the graphite sheet.

Under the circumstances, an object of the invention is to provide a structure having a metal material for heat radiation that is capable of favorably radiating heat from a heat generating component.

### Solution to Problem

As a result of earnest investigations made by the present inventors, it has been found that the object can be achieved by a structure having a metal material for heat radiation having a structure containing a heat generating component and a heat radiating member for radiating heat from the heat generating component, in which the heat radiating member is provided to have a layer structure containing a metal material for heat radiation and a graphite sheet.

The invention having been completed based on the aforementioned knowledge provides, in one aspect, a structure having a metal material for heat radiation, containing a heat generating component and a heat radiating member for radiating heat from the heat generating component, wherein the heat radiating member has a layer structure containing a metal material for heat radiation and a graphite sheet.

In the structure having a metal material for heat radiation according to one embodiment of the invention, the heat radiating member contains the graphite sheet and the metal material for heat radiation in this order from the side of the heat generating component.

In the structure having a metal material for heat radiation according to another embodiment of the invention, the heat radiating member contains the metal material for heat radiation and the graphite sheet in this order from the side of the heat generating component.

In the structure having a metal material for heat radiation according to still another embodiment of the invention, the heat radiating member contains a plurality of the graphite sheets.

In the structure having a metal material for heat radiation according to still another embodiment of the invention, the heat radiating member contains the graphite sheet, the metal material for heat radiation, and the graphite sheet in this order from the side of the heat generating component.

In the structure having a metal material for heat radiation according to still another embodiment of the invention, the heat generating component is disposed to face the entire surface of the heat radiating member.

In the structure having a metal material for heat radiation according to still another embodiment of the invention, the heat generating component contains a heat generator and a heat generator protective member provided to cover a part or the entire of the heat generator, and the heat radiating member is disposed on the side opposite to the heat generator with respect to the heat generator protective member.

In the structure having a metal material for heat radiation according to still another embodiment of the invention, the structure further contains a thermal conductive resin between the heat generator and the heat generator protective member.

In the structure having a metal material for heat radiation according to still another embodiment of the invention, the metal material for heat radiation contains a surface on the side of the heat generating component and/or a surface on the side opposite to the heat generating component that has a color difference ΔL based on JIS 28730 satisfying ΔL≦−40.

In the structure having a metal material for heat radiation according to still another embodiment of the invention, the metal material for heat radiation contains a surface on the side of the heat generating component and/or a surface on the side opposite to the heat generating component that has a radiation factor of 0.03 or more.

In the structure having a metal material for heat radiation according to still another embodiment of the invention, the metal material for heat radiation contains a surface treatment layer provided on a surface on the side of the heat generating component and/or a surface on the side opposite to the heat generating component, and the surface treatment layer contains one or more layers selected from the group consisting of a roughening treatment layer, a heat resistant layer, a rust preventing layer, a chromate treatment layer, a silane coupling treatment layer, a plated layer, and a resin layer.

In the structure having a metal material for heat radiation according to still another embodiment of the invention, the metal material for heat radiation contains copper, a copper alloy, aluminum, an aluminum alloy, iron, an iron alloy, nickel, a nickel alloy, gold, a gold alloy, silver, a silver alloy, a platinum group metal, a platinum group metal alloy, chromium, a chromium alloy, magnesium, a magnesium alloy, tungsten, a tungsten alloy, molybdenum, a molybdenum alloy, lead, a lead alloy, tantalum, a tantalum alloy, tin, a tin alloy, indium, an indium alloy, zinc, or a zinc alloy.

In the structure having a metal material for heat radiation according to still another embodiment of the invention, the metal material for heat radiation contains copper, a copper alloy, aluminum, an aluminum alloy, iron, an iron alloy, nickel, a nickel alloy, zinc, or a zinc alloy.

In the structure having a metal material for heat radiation according to still another embodiment of the invention, the metal material for heat radiation contains phosphor bronze, Corson alloy, red brass, brass, nickel silver, or other copper alloys.

In the structure having a metal material for heat radiation according to still another embodiment of the invention, the metal material for heat radiation is a metal strip, a metal plate, or a metal foil.

In the structure having a metal material for heat radiation according to still another embodiment of the invention, the metal material for heat radiation contains a surface on the side of the heat generating component and/or a surface on the side opposite to the heat generating component that has a surface roughness Sz of 5 μm or more measured with a laser microscope with laser light having a wavelength of 405 nm.

In the structure having a metal material for heat radiation according to still another embodiment of the invention, the metal material for heat radiation contains a surface on the side of the heat generating component and/or a surface on the side opposite to the heat generating component that has a surface roughness Sa of 0.13 μm or more measured with a laser microscope with laser light having a wavelength of 405 nm.

In the structure having a metal material for heat radiation according to still another embodiment of the invention, the metal material for heat radiation contains a surface on the side of the heat generating component and/or a surface on the side opposite to the heat generating component that has a surface roughness Sku of 6 or more measured with a laser microscope with laser light having a wavelength of 405 nm.

In the structure having a metal material for heat radiation according to still another embodiment of the invention, the heat radiating member further contains a substance having thermal conductivity provided on the side of the heat generating component.

In the structure having a metal material for heat radiation according to still another embodiment of the invention, the substance has a thermal conductivity of 0.5 W/(m·K) or more.

The invention provides, in another aspect, a printed circuit board containing the structure having a metal material for heat radiation according to the invention.

The invention provides, in still another aspect, an electronic apparatus containing the structure having a metal material for heat radiation according to the invention.

The invention provides, instill another aspect, a metal material for heat radiation containing one or more surfaces, wherein at least one of the surfaces satisfies one or more of the following items (1) to (5), and the metal material for heat radiation is to be adhered with a graphite sheet and to be used as a heat radiating member:

(1) the surface having a color difference ΔL based on JIS Z8730 of ΔL≦−40;

(2) the surface having a radiation factor of 0.03 or more;

(3) the surface having a surface roughness Sz of 5 μm or more measured with a laser microscope with laser light having a wavelength of 405 nm;

(4) the surface having a surface roughness Sa of 0.13 μm or more measured with a laser microscope with laser light having a wavelength of 405 nm; and

(5) the surface having a surface roughness Sku of 6 or more measured with a laser microscope with laser light having a wavelength of 405 nm.

### Advantageous Effects of Invention

According to the invention, a structure having a metal material for heat radiation can be provided that is capable of favorably radiating heat from a heat generating component.

### BRIEF DESCRIPTION OF DRAWINGS

FIG. 1 is a schematic cross sectional view showing the structure having a metal material for heat radiation of Reference Example.

FIG. 2 is a schematic cross sectional view showing the structures having a metal material for heat radiation of Examples 1a to 1c.

FIG. 3 is a schematic cross sectional view showing the structures having a metal material for heat radiation of Examples 2a to 2c.

FIG. 4 is a schematic cross sectional view showing the structures having a metal material for heat radiation of Examples 3a to 3c.

FIG. 5 is an illustration showing the position of the heat generator provided with respect to the heat radiating member in Reference Example and Examples.

FIG. 6 is an illustration showing the maximum temperatures of the outermost surfaces (heat radiating surfaces) of the heat radiating members in Reference Example and Examples.

### DESCRIPTION OF EMBODIMENTS

The structure having a metal material for heat radiation of the invention contains a heat generating component and a heat radiating member for radiating heat from the heat generating component, in which the heat radiating member has a layer structure containing a metal material for heat radiation and a graphite sheet. The heat generating component means a member that generates heat or a member containing as apart thereof the member that generates heat, and is a concept that includes, for example, an electric component, an application processor, an IC chip, and the like.

The heat generating component may contain a heat generator and a heat generator protective member provided to cover a part or the entire of the heat generator, and the heat radiating member may be disposed on the side opposite to the heat generator with respect to the heat generator protective member. A thermal conductive resin may be provided between the heat generator and the heat generator protective member, and thereby the heat from the heat generator can be efficiently conducted from the heat generator protective member to the heat radiating member.

The heat generator protective member may be provided to cover a part or the entire of the heat generating component, and may have a concept that includes, for example, a heat generating component cover, an electromagnetic wave shielding material, an electromagnetic wave shielding cover, and the like. The heat generator protective member may be any member that can absorb heat and radiate the heat outward, and examples of the material used therefor include various known materials including iron, copper, aluminum, magnesium, nickel, vanadium, zinc, magnesium, titanium, alloys of these metals, stainless steel, an inorganic material, ceramics (such as silicon nitride) , a metal oxide, a compound, an organic material, graphene, graphite, carbon nanotubes, black lead, a conductive polymer, a high thermal conductive resin, a polycarbonate resin, a polyamide resin, a polybutylene terephthalate resin, a polyacetal resin, and a modified polyphenylene ether resin. The heat generator protective member preferably has thermal conductivity.

The heat radiating member of the structure having a metal material for heat radiation of the invention has a layer structure containing a metal material for heat radiation and a graphite sheet. The metal material for heat radiation favorably conducts the heat from the heat generating component not only in the horizontal direction of the heat radiating member but also in the vertical direction (i.e. , the thickness direction) thereof, and thus the heat from the heat generating component can be radiated by favorably conducting the heat from the heat radiating member toward the upper surface. Accordingly, malfunction of the heat generating component due to the temperature rise can be suppressed from occurring.

In particular, mobile equipments, such as a smartphone and a tablet PC, are being actively developed in recent years, and a smartphone, a tablet PC, and the like are undergoing the increase of the number of CPU mounted on the application processor and the increase of the operation clock frequency thereof, for running high load applications. The increase of the power consumption of the CPU thereby increases the temperature of the application processor, and actualizes the so-called “heat spot” problem, which causes low temperature burn injury on carrying the smartphone. The countermeasures for the heat spot include the decrease of the operation clock frequency and the force quit of the application in use on reaching a prescribed temperature, but these countermeasures have a problem that the highly functional application processor mounted cannot sufficiently exert the function thereof . The use of the structure having a metal material for heat radiation of the invention can radiate the heat from the application processor (heat generating component) , and thus the temperature of the application processor (heat generating component) can be favorably suppressed from being increased, thereby sufficiently exerting the function of the highly functional application processor.

In the structure having a metal material for heat radiation of the invention, the heat radiating member may contain the graphite sheet and the metal material for heat radiation in this order from the side of the heat generating component. The heat radiating member may contain the metal material for heat radiation and the graphite sheet in this order from the side of the heat generating component. The heat radiating member may contain the graphite sheet, the metal material for heat radiation, and the graphite sheet in this order from the side of the heat generating component.

The heat radiating member and the heat generating component may be fixed to each other by providing an adhesive tape (such as a double-sided adhesive tape) between them. In the case where the metal material for heat radiation and the heat generating component can be fixed to each other through pressure bonding or the like, the adhesive tape may not be provided.

In the structure having a metal material for heat radiation of the invention, the heat generating component may be disposed to face the entire surface of the heat radiating member. Such constitution of the structure having a metal material for heat radiation of the invention also can favorably radiate the heat from the heat generator.

The heat radiating member of the structure having a metal material for heat radiation of the invention may contain plural graphite sheets. According to the constitution, the heat radiating member may have better heat radiating property.

The metal material for heat radiation used in the invention may be formed of copper, a copper alloy, aluminum, an aluminum alloy, iron, an iron alloy, nickel, a nickel alloy, gold, a gold alloy, silver, a silver alloy, a platinum group metal, a platinum group metal alloy, chromium, a chromium alloy, magnesium, a magnesium alloy, tungsten, a tungsten alloy, molybdenum, a molybdenum alloy, lead, a lead alloy, tantalum, a tantalum alloy, tin, a tin alloy, indium, an indium alloy, zinc, or a zinc alloy.

The metal material for heat radiation may be a metal strip, a metal plate, or a metal foil.

Typical examples of the copper include copper having a purity of 95% by mass or more, more preferably 99.90% by mass or more, for example, a phosphorus-deoxidized copper (JIS H3100, alloy number: C1201, C1220, or C1221), an oxygen-free copper (JIS H3100, alloy number: C1020), and a tough pitch copper (JIS H3100, alloy number: C1100), and an electrolytic copper foil defined in JIS H0500 and JIS H3100. Copper or a copper alloy containing one or more of Sn, Ag, Au, Co, Cr, Fe, In, Ni, P, Si, Te, Ti, Zn, B, Mn, and Zr in a total amount of from 0.001 to 4.0% by mass may also be used.

Examples of the copper alloy include phosphor bronze, Corson alloy, red brass, brass, nickel silver, and other copper alloys. As the copper and the copper alloy, copper and copper alloys defined in JIS H3100 to JIS H3510, JIS H5120, JIS H5121, JIS C2520 to JIS C2801, and JIS E2101 to JIS E2102 can also be used in the invention. In the description herein, the JISs cited for showing the standards of metals are the JISs of the 2001 edition unless otherwise indicated.

The phosphor bronze typically means a copper alloy containing copper as the major component, Sn, and P in a smaller amount than Sn. As one example, the phosphor copper may have a composition containing from 3.5 to 11% by mass of Sn, from 0.03 to 0.35% by mass of P, and the balance of copper and unavoidable impurities. The phosphor bronze may contain elements including Ni, Zn, and the like in a total amount of 1.0% by mass or less.

The Corson alloy typically means a copper alloy containing an element that forms a compound with Si (for example, one or more of Ni, Co, and Cr) added thereto, which is precipitated as secondary phase particles in the mother phase. As one example, the Corson alloy may have a composition constituted by from 0.5 to 4.0% by mass of Ni, from 0.1 to 1.3% by mass of Si, and the balance of copper and unavoidable impurities. As another example, the Corson alloy may have a composition constituted by from 0.5 to 4.0% by mass of Ni, from 0.1 to 1.3% by mass of Si, from 0.03 to 0.5% by mass of Cr, and the balance of copper and unavoidable impurities. As still another example, the Corson alloy may have a composition constituted by from 0.5 to 4.0% by mass of Ni, from 0.1 to 1.3% by mass of Si, from 0.5 to 2.5% by mass of Co, and the balance of copper and unavoidable impurities. As still another example, the Corson alloy may have a composition constituted by from 0.5 to 4.0% by mass of Ni, from 0.1 to 1.3% by mass of Si, from 0.5 to 2.5% by mass of Co, from 0.03 to 0.5% by mass of Cr, and the balance of copper and unavoidable impurities. As still another example, the Corson alloy may have a composition constituted by from 0.2 to 1.3% by mass of Si, from 0.5 to 2.5% by mass of Co, and the balance of copper and unavoidable impurities. The Corson alloy may arbitrarily contain other elements (such as Mg, Sn, B, Ti, Mn, Ag, P, Zn, As, Sb, Be, Zr, Al, and Fe) added thereto. These elements may be added generally in a total amount up to approximately 5.0% by mass. For example, as still another example, the Corson alloy may have a composition constituted by from 0.5 to 4.0% by mass of Ni, from 0.1 to 1.3% by mass of Si, from 0.01 to 2.0% by mass of Sn, from 0.01 to 2.0% by mass of Zn, and the balance of copper and unavoidable impurities.

In the invention, the red brass means a copper alloy that is an alloy of copper and zinc containing zinc in an amount of from 1 to 20% by mass, and preferably from 1 to 10% by mass. The red brass may contain tin in an amount of from 0.1 to 1.0% by mass.

In the invention, the brass means a copper alloy that is an alloy of copper and zinc particularly containing zinc in an amount of 20% by mass or more. The upper limit of zinc is not particularly limited, and may be 60% by mass or less, and preferably 45% by mass or less or 40% by mass or less.

In the invention, the nickel silver means a copper alloy containing copper as the major component, containing from 60% by mass to 75% by mass of copper, from 8.5% by mass to 19.5% by mass of nickel, and from 10% by mass to 30% by mass of zinc.

In the invention, the other copper alloys mean copper alloys containing one kind or two or more kinds of Zn, Sn, Ni, Mg, Fe, Si, P, Co, Mn, Zr, Ag, B, Cr, and Ti in a total amount of 8.0% by mass or less, and the balance of copper and unavoidable impurities.

The aluminum and the aluminum alloy used may be, for example, one containing A1 in an amount of 40% by mass or more, 80% by mass or more, or 99% by mass or more. Examples thereof used include aluminum and aluminum alloys defined in JIS H4000 to JIS H4180, JIS H5202, JIS H5303, and JIS 23232 to JIS 23263. For example, aluminum or an alloy thereof having an Al content of 99.00% by mass or more represented by the aluminum alloy numbers 1085, 1080, 1070, 1050, 1100, 1200, 1N00, and 1N30 defined in JIS H4000 may be used.

The nickel and the nickel alloy used may be, for example, ones containing Ni in an amount of 40% by mass or more, 80% by mass or more, or 99.0% by mass or more. Examples thereof used include nickel and nickel alloys defined in JIS H4541 to JIS H4554, JIS H5701, JIS G7604 to JIS G7605, and JIS C2531. For example, nickel or an alloy thereof having a Ni content of 99.0% by mass or more represented by the alloy numbers NW 2200 and NW2201 defined in JIS H4551 may be used.

The iron alloy used may be, for example, soft steel, carbon steel, an iron-nickel alloy, steel, or the like. Examples thereof used include iron and iron alloys defined in JIS G3101 to JIS G7603, JIS C2502 to JIS C8380, JIS A5504 to JIS A6514, and JIS E1101 to JIS E5402-1. The soft steel used may be soft steel having a carbon content of 0.15% by mass or less, and soft steel described in JIS G3141 and the like may be used. The iron-nickel alloy used may contain Ni in an amount of from 35 to 85% by mass with the balance of Fe and unavoidable impurities, and specifically may be an iron-nickel alloy described in JIS C2531.

The zinc and the zinc alloy used may be, for example, ones containing Zn in an amount of 40% by mass or more, 80% by mass or more, or 99.0% by mass or more. Examples thereof used include zinc and zinc alloys defined in JIS H2107 to JIS H5301.

The lead and the lead alloy used may be, for example, ones containing Pb in an amount of 40% by mass or more, 80% by mass or more, or 99.0% by mass or more. Examples thereof used include lead and lead alloys defined in JIS H4301 to JIS H4312 and JIS H5601.

The magnesium and the magnesium alloy used may be, for example, ones containing Mg in an amount of 40% by mass or more, 80% by mass or more, or 99.0% by mass or more. Examples thereof used include magnesium and magnesium alloys defined in JIS H4201 to JIS H4204, JIS H5203 to JIS H5303, and JIS H6125.

The tungsten and the tungsten alloy used may be, for example, ones containing W in an amount of 40% by mass or more, 80% by mass or more, or 99.0% by mass or more. Examples thereof used include tungsten and tungsten alloys defined in JIS H4463.

The molybdenum and the molybdenum alloy used may be, for example, ones containing Mo in an amount of 40% by mass or more, 80% by mass or more, or 99.0% by mass or more.

The tantalum and the tantalum alloy used may be, for example, ones containing Ta in an amount of 40% by mass or more, 80% by mass or more, or 99.0% by mass or more. Examples thereof used include tantalum and tantalum alloys defined in JIS H4701.

The tin and the tin alloys used may be, for example, ones containing Sn in an amount of 40% by mass or more, 80% by mass or more, or 99.0% by mass or more. Examples thereof used include tin and tin alloys defined in JIS H5401.

The indium and the indium alloy used may be, for example, ones containing In in an amount of 40% by mass or more, 80% by mass or more, or 99.0% by mass or more.

The chromium and the chromium alloy used may be, for example, ones containing Cr in an amount of 40% by mass or more, 80% by mass or more, or 99.0% by mass or more.

The silver and the silver alloy used may be, for example, ones containing Ag in an amount of 40% by mass or more, 80% by mass or more, or 99.0% by mass or more.

The gold and the gold alloy used may be, for example, ones containing Au in an amount of 40% by mass or more, 80% by mass or more, or 99.0% by mass or more.

The platinum group is the generic name for ruthenium, rhodium, palladium, osmium, iridium, and platinum. The platinum group metal and the platinum group metal alloy used may be, for example, ones containing at least one element selected from the element group of Pt, Os, Ru, Pd, Ir, and Rh in an amount of 40% by mass or more, 80% by mass or more, or 99.0% by mass or more.

The metal material for heat radiation preferably has a thickness of 18 μm or more. When the thickness of the metal material for heat radiation is less than 18 μm, there may be a possibility that the sufficient heat radiation effect cannot be obtained. The thickness of the metal material for heat radiation is more preferably 35 μm or more, further preferably 50 μm or more, still further preferably 65 μm or more, and still further preferably 70 μm or more.

The surface of the metal material for heat radiation on the side of the heat generating component and/or on the side opposite to the heat generating component preferably has a surface roughness Sz (i.e., the maximum height of the surface) of 5 μm or more measured with a laser microscope with laser light having a wavelength of 405 nm. When the surface roughness Sz of the surface of the metal material for heat radiation on the side of the heat generating component and/or on the side opposite to the heat generating component is less than 5 μm, there may be a possibility that the heat radiation property of the heat generating component becomes inferior. The surface roughness Sz of the surface of the metal material for heat radiation on the side of the heat generating component and/or on the side opposite to the heat generating component is preferably 7 μm or more, more preferably 10 μm or more, further preferably 14 μm or more, still further preferably 15 μm or more, and still further preferably 25 μm or more. The upper limit thereof is not particularly determined, and may be, for example, 90 μm or less, 80 μm or less, or 70 μm or less. In the case where the surface roughness Sz exceeds 90 μm, there may be a case where the productivity is reduced.

In the case where the metal material for heat radiation has a surface treatment layer, such as a heat resistant layer, a rust preventing layer, a chromate treatment layer, a silane coupling treatment layer, and a resin layer, on the surface thereof, the “surface on the side of the heat generating component” and the “surface on the side opposite to the heat generating component ” of the metal material for heat radiation each mean the outermost surface thereof after providing the surface treatment layer.

The surface of the metal material for heat radiation on the side of the heat generating component and/or on the side opposite to the heat generating component preferably has a surface roughness Sa (i.e., the arithmetic average roughness of the surface) of 0.13 μm or more. When the surface roughness Sa of the surface of the metal material for heat radiation on the side of the heat generating component and/or on the side opposite to the heat generating component is less than 0.13 μm, there may be a possibility that the heat radiation property of the heat generating component becomes inferior. The surface roughness Sa of the surface of the metal material for heat radiation on the side of the heat generating component and/or on the side opposite to the heat generating component is more preferably 0.20 μm or more, further preferably 0.25 μm or more, and still further preferably 0.30 μm or more, and is typically from 0.1 to 1.0 μm, and more typically from 0.1 to 0.9 μm.

The surface of the metal material for heat radiation on the side of the heat generating component and/or on the side opposite to the heat generating component preferably has a surface roughness Sku (i.e. , the kurtosis of the surface height distribution; kurtosis number) of 6 or more. When the Sku of the surface of the metal material for heat radiation on the side of the heat generating component and/or on the side opposite to the heat generating component is less than 6, there may be a possibility that the heat radiation property of the heat generating component becomes inferior. The Sku of the surface of the metal material for heat radiation on the side of the heat generating component and/or on the side opposite to the heat generating component is more preferably 9 or more, further preferably 10 or more, still further preferably 40 or more, and still further preferably 60 or more, and is typically from 3 to 200, and more typically from 4 to 180.

The surface of the metal material for heat radiation on the side of the heat generating component and/or on the side opposite to the heat generating component preferably has a color difference ΔL based on JIS Z8730 satisfying ΔL≦−40. When the color difference ΔL on the surface of the metal material for heat radiation on the side of the heat generating component and/or on the side opposite to the heat generating component is controlled to satisfy ΔL≦−40, radiation heat, convection heat, and the like generated from the heat generating component can be favorably absorbed. The color difference AL preferably satisfies ΔL≦−45, more preferably ΔL≦−50, further preferably ΔL≦−55, still further preferably ΔL≦−58, still further preferably ΔL≦−60, still further preferably ΔL≦−65, still further preferably ΔL≦−68, and still further preferably ΔL≦−70. The lower limit of the ΔL may not be necessarily determined, and may satisfy, for example, ΔL≧−90, ΔL≧−88, ΔL≧−85, ΔL≧−83, ΔL≧−80, ΔL≧−78, or ΔL≧−75. The color difference ΔL based on JIS Z8730 of the surface can be measured with a colorimeter, MiniScan XE Plus, produced by Hunter Associates Laboratory, Inc.

The color difference ΔL can be controlled, for example, by using a copper material as a substrate of the metal material for heat radiation, and forming roughening particles on the surface of the copper material. The color difference ΔL can be achieved in such a manner that primary roughening particles are formed by using an electrolytic solution containing at least one element of copper, nickel, and cobalt at an increased current density (for example, from 30 to 50 A/dm²) for a shortened treatment time (for example, from 0.5 to 1.5 seconds) , and thereon secondary roughening particles are formed at a high current density (for example, from 20 to 40 A/dm²) for a short treatment time (for example, from 0.1 to 0.5 seconds).

A surface treatment layer may be provided on the surface of the metal material for heat radiation on the side of the heat generating component and/or on the side opposite to the heat generating component. The surface treatment layer may contain one or more layers selected from the group consisting of a roughening treatment layer, a heat resistant layer, a rust preventing layer, a chromate treatment layer, a silane coupling treatment layer, a plated layer, and a resin layer.

A roughening treatment for forming the roughening treatment layer may be performed, for example, by forming roughening particles with copper or a copper alloy. The roughening treatment may be a fine treatment. The roughening treatment layer may be a layer formed of an elemental substance of any one of copper, nickel, cobalt, phosphorus, tungsten, arsenic, molybdenum, chromium, and zinc, or an alloy containing one or more of them, or the like. After forming the roughening particles with copper or a copper alloy, a roughening treatment may be further performed to provide secondary particles or tertiary particles with, for example, an elemental substance or an alloy of nickel, cobalt, copper, or zinc. Thereafter, a heat resistant layer or a rust preventing layer maybe formed with, for example, an elemental substance or an alloy of nickel, cobalt, copper, or zinc, and further on the surface thereof, such treatments as a chromate treatment, a silane coupling treatment, and the like may be performed. In alternative, without a roughening treatment performed, a plated layer may be formed, or a heat resistant layer or a rust preventing layer may be formed with, for example, an elemental substance or an alloy of nickel, cobalt, copper, or zinc, and further on the surface thereof, such a treatment as a chromate treatment, a silane coupling treatment, and the like may be performed. Accordingly, one or more layer selected from the group consisting of a heat resistant layer, a rust preventing layer, a chromate treatment layer, a silane coupling treatment layer, a plated layer, and a resin layer maybe formed on the surface of the roughening treatment layer. The heat resistant layer, the rust preventing layer, the chromate treatment layer, the silane coupling treatment layer, the plated layer, and the resin layer each may be formed of plural layers (for example, two or more layers, or three or more layers). The plated layer can be formed by wet plating, such as electro plating, electroless plating, and dip plating, or dry plating, such as sputtering, CVD, and PDV.

The chromate treatment layer means a layer treated with a liquid containing chromic anhydride, chromic acid, dichromic acid, a chromate salt, or a dichromate salt. The chromate treatment layer may contain such elements as cobalt, iron, nickel, molybdenum, zinc, tantalum, copper, aluminum, phosphorus, tungsten, tin, arsenic, titanium, and the like (which may be in any form, for example, a metal, an alloy, an oxide, a nitride, and a sulfide). Specific examples of the chromate treatment layer include a chromate treatment layer treated with an aqueous solution of chromic anhydride or potassium dichromate, and a chromate treatment layer treated with a treatment liquid containing chromic anhydride or potassium dichromate and zinc.

The heat resistant layer and the rust preventing layer used may be a known heat resistant layer and a known rust preventing layer. For example, the heat resistant layer and/or the rust preventing layer maybe a layer containing one or more element selected from the group consisting of nickel, zinc, tin, cobalt, molybdenum, copper, tungsten, phosphorus, arsenic, chromium, vanadium, titanium, aluminum, gold, silver, a platinum group element, iron, and tantalum, and may be a metal layer or an alloy layer formed of one or more element selected from the group consisting of nickel, zinc, tin, cobalt, molybdenum, copper, tungsten, phosphorus, arsenic, chromium, vanadium, titanium, aluminum, gold, silver, a platinum group element, iron, and tantalum. The heat resistant layer and/or the rust preventing layer may contain an oxide, a nitride, or a silicide of one or more element selected from the group consisting of nickel, zinc, tin, cobalt, molybdenum, copper, tungsten, phosphorus, arsenic, chromium, vanadium, titanium, aluminum, gold, silver, a platinum group element, iron, and tantalum. The heat resistant layer and/or the rust preventing layer may be a layer containing a nickel-zinc alloy. The heat resistant layer and/or the rust preventing layer may be a nickel-zinc alloy layer. The heat resistant layer and/or the rust preventing layer may be a layer of an organic material. The layer of an organic material may contain one or more organic material selected from the group consisting of a nitrogen-containing organic compound, a sulfur-containing organic compound, and a carboxylic acid. The nitrogen-containing organic compound used is specifically preferably a triazole compound having a substituent, such as 1,2,3-benzotriazole, carboxybenzotriazole, N′,N′-bis(benzotriazolylmethyl)urea, 1H-1,2,4-triazole, and 3-amino-1H-1,2,4-triazole. The sulfur-containing compound used is preferably mercaptobenzothiazole, sodium 2-mercaptobenzothiazole, thiocyanuric acid, or 2-benzimidazolthiol. The carboxylic acid used is particularly preferably a monocarboxylic acid, and therein oleic acid, linoleic acid, linolenic acid, or the like are preferably used. The heat resistant layer and/or the rust preventing layer may be a known organic rust preventing film containing carbon.

A silane coupling agent used for the silane coupling treatment may be a known silane coupling agent, and examples thereof used include an amino silane coupling agent, an epoxy silane coupling agent, and a mercapto silane coupling agent. Examples of the silane coupling agent used also include vinyltrimethoxysilane, vinylphenyltrimethoxysilane, γ-methacryloxypropyltrimethoxysilane, γ-glycidoxypropyltrimethoxysilane, 4-glycidylbutyltrimethoxysilane, γ-aminopropyltriethoxysilane, N-β-(aminoethyl)-y-aminopropyltrimethoxysilane, N-3-(4-(3-aminopropoxy)butoxy)propyl-3-aminopropyltrimetho xysilane, imidazole silane, triazine silane, and γ-mercaptopropyltrimethoxysilane.

The resin layer used may be a layer containing a known resin. The resin layer is preferably a resin layer containing a resin that radiates heat. The resin used in the resin layer preferably has a high radiation factor. The resin layer used may be a known heat radiation sheet. The resin layer used may be a resin layer containing one or more selected from the group consisting of a silicone resin, an acrylic resin, a urethane resin, ethylene-propylene-diene rubber, synthetic rubber, an epoxy resin, a fluorine resin, a polyimide resin, a liquid crystal polymer, a polyamide resin, a silicone oil, a silicone grease, and a silicone oil compound. The resin layer may contain one or more selected from the group consisting of a metal, ceramics, an inorganic material, and an organic material, as a filler. The metal may be any one metal selected from the group consisting of Ag, Cu, Ni, Zn, Au, Al, a platinum group element, and Fe, or an alloy containing any one of them. The ceramics may be one or more selected from the group consisting of an oxide, a nitride, a silicide, and a carbide. The oxide may contain one or more selected from the group consisting of aluminum oxide, silicon oxide, zinc oxide, copper oxide, iron oxide, zirconium oxide, beryllium oxide, titanium oxide, and nickel oxide. The nitride may contain one or more selected from the group consisting of boron nitride, aluminum nitride, silicon nitride, and titanium nitride. The silicide may contain one or more selected from the group consisting of silicon carbide, molybdenum silicide (e.g., MoSi₂ and Mo₂Si₃) , tungsten silicide (e.g., WSi₂ and W₅Si₃), tantalum silicide (e.g., TaSi₂), chromium silicide, and nickel silicide. The carbide may contain one or more selected from the group consisting of silicon carbide, tungsten carbide, calcium carbide, and boron carbide. The inorganic material may contain one or more selected from the group consisting of graphite, carbon nanotubes, fullerene, diamond, graphene, and ferrite.

The surface of the metal material for heat radiation on the side of the heat generating component and/or on the side opposite to the heat generating component preferably has a radiation factor of 0.03 or more. When the radiation factor of the surface of the metal material for heat radiation on the side of the heat generating component and/or on the side opposite to the heat generating component is 0.03 or more, the heat from the heat generating component can be favorably radiated. The radiation factor of the surface of the metal material for heat radiation on the side of the heat generating component and/or on the side opposite to the heat generating component is more preferably 0.04 or more, more preferably 0.05 or more, more preferably 0.06 or more, more preferably 0.092 or more, more preferably 0.10 or more, further preferably 0.123 or more, further preferably 0.154 or more, further preferably 0.185 or more, further preferably 0.246 or more, preferably 0.3 or more, preferably 0.4 or more, preferably 0.5 or more, preferably 0.6 or more, and preferably 0.7 or more.

The upper limit of the radiation factor of the surface of the metal material for heat radiation on the side of the heat generating component and/or on the side opposite to the heat generating component may not be necessarily determined, and is typically 1 or less, more typically 0.99 or less, more typically 0.95 or less, more typically 0.90 or less, more typically 0.85 or less, and more typically 0.80 or less. When the radiation factor of the surface of the metal material for heat radiation on the side of the heat generating component and/or on the side opposite to the heat generating component is 0.90 or less, the productivity may be enhanced.

The metal material for heat radiation may be a metal material for heat radiation containing one or more surfaces, at least one of the surfaces may satisfy one or more of the following items (1) to (5), and the metal material for heat radiation may be adhered with a graphite sheet and to be used:

(1) the surface having a color difference ΔL based on JIS 28730 of ΔL≦−40;

(2) the surface having a radiation factor of 0.03 or more;

(3) the surface having a surface roughness Sz of 5 μm or more measured with a laser microscope with laser light having a wavelength of 405 nm;

(4) the surface having a surface roughness Sa of 0.13 μm or more measured with a laser microscope with laser light having a wavelength of 405 nm; and

(5) the surface having a surface roughness Sku of 6 or more measured with a laser microscope with laser light having a wavelength of 405 nm.

The color difference ΔL based on JIS 28730, the radiation factor, and the surface roughnesses Sz, Sa, and Sku measured with a laser microscope with laser light having a wavelength of 405 nm of the surface of the metal material for heat radiation are preferably controlled to the ranges of the color difference ΔL based on JIS 28730, the radiation factor, and the surface roughnesses Sz, Sa, and Sku measured with a laser microscope with laser light having a wavelength of 405 nm of the surface of the metal material for heat radiation on the side of the heat generating component, respectively. The metal material for heat radiation can be adhered with a graphite sheet and can be used as a heat radiating member.

In the structure having a metal material for heat radiation of the invention, the heat radiating member may further contain a substance having thermal conductivity on the face thereof on the side of the heat generating component. According to the constitution, the heat from the heat generating component can be favorably radiated.

The substance having thermal conductivity used may be a substance containing one or more selected from the group consisting of a resin, a metal, ceramics, an inorganic material, and an organic material. The resin used may be one or more selected from the group consisting of a silicone resin, an acrylic resin, a urethane resin, ethylene-propylene-diene rubber, synthetic rubber, natural rubber, an epoxy resin, a polyethylene resin, a polyphenylene sulfide (PPS) resin, a polybutylene terephthalate (PBT) resin, a fluorine resin, a polyimide resin, a polycarbonate resin, a liquid crystal polymer, a polyamide resin, a silicone oil, a silicone grease, and a silicone oil compound. The resin may contain one or more selected from the group consisting of a metal, ceramics, an inorganic material, and an organic material, as a filler. The metal, the ceramics, the inorganic material, and the organic material may be the metal, the ceramics, the inorganic material, and the organic material contained in the resin layer. The form of the metal may be a bulk form, a particle form, a strand form, a flake form, or a mesh form.

The substance having thermal conductivity preferably has a thermal conductivity of 0 .5 W/ (m·K) or more, preferably 1 W/ (m·K) or more, preferably 2 W/ (m·K) or more, preferably 3 W/ (m·K) or more, preferably 5 W/ (m·K) or more, preferably 10 W/ (m·K) or more, more preferably 20 W/ (m·K) or more, more preferably 30 W/ (m·K) or more, and further preferably 35 W/ (m·K) or more. The upper limit of the thermal conductivity of the substance is not particularly limited, and for example, 4,000 W/ (m·K) or less, 3,000 W/ (m·K) or less, or 2,500 W/ (m·K) or less. The thermal conductivity of the substance having thermal conductivity is preferably the thermal conductivity in the direction in parallel to the thickness direction of the substance. The thickness direction of the substance having thermal conductivity herein is the direction in parallel to the thickness direction of the metal material for heat radiation.

A printed wiring board can be produced by using the structure having a metal material for heat radiation of the invention, and a printed circuit board may be produced by mounting electric components on the printed wiring board. An electronic apparatus may be produced by using the printed circuit board, and an electronic apparatus may be produced by using the printed circuit board having electronic components mounted thereon. The structure having a metal material for heat radiation of the invention may be used for heat radiation of a heat generating component of various electronic apparatuses, such as a display, a IC chip, a capacitor, an inductor, a connector, a terminal, a memory, an LSI, a chassis, a CPU, a circuit, and an integrated circuit. For example, the structure having a metal material for heat radiation can be used for heat radiation of an application processor or the like of a mobile equipment, such as a smartphone and a tablet PC, as the heat generating component.

### EXAMPLES

1. Preparation of Heat Radiating Member

As a heat radiating member, a graphite sheet having a thickness of 25 μm and the following metal materials for heat radiation (thickness: 50 μm, 70 μm, and 100 μm) were prepared.

### Metal Material for Heat Radiation

Metal material: copper substrate (rolled copper foil, having a composition of a tough pitch copper defined in JIS H3100, alloy number: C1100, having Ag added thereto in an amount of 200 ppm by mass, obtained by repeatedly performing rolling and annealing, and then rolling with an oil film equivalent amount of 25,000 in the final cold rolling in the production of the rolled copper foil)

Surface treatment: electroplating treatments (performed (1) and (2) in this order)

Plating solution conditions (1):

Cu concentration: 10 g/L, Sulfuric acid concentration: 20 g/L

pH: 1.0

Temperature: 26° C.

Current density: 45 A/dm²

Plating time: 0.8 second×2

Current density: 4 A/dm²

Plating time: 2.0 seconds×2

Plating solution conditions (2):

Cu concentration: 8 g/L, Co concentration: 8 g/L, Ni concentration: 8 g/L

pH: 3.5

Temperature: 35° C.

Current density: 31 A/dm²

Plating time: 0.6 second×2

Thickness: 70

Color difference AL of the surface of the metal material for heat radiation on the side of the heat generating component: −54.2

Surface roughnesses of the surface of the metal material for heat radiation on the side of the heat generating component, Sz: 25.1 μm, Sa: 0.43 μm, Sku: 21.4

The electroplated surfaces of the metal materials for heat radiation were subjected to the heat resistant plating treatment and the rust preventing plating treatment below.

### Heat Resistant Plating Treatment

Ni concentration: 12 g/L, Co concentration: 3 g/L

pH: 2.0

Temperature: 50° C.

Current density: 15 A/dm²

Plating time: 0.4 second×2

### Rust Preventing Plating Treatment

Cr concentration: 3.0 gL/L, Zn concentration: 0.3 g/L

pH: 2.0

Temperature: 55° C.

Current density: 2.0 A/dm²

Plating time: 0.5 second×2

### Color Difference

The surfaces of the metal materials for heat radiation on the side of the heat generating component were evaluated for the color difference in the following manner.

The color difference of the surface of the metal material for heat radiation on the side of the heat generating component with respect to the object color of the white plate (assuming D65 as the light source and 10° for the view field, the white plate had tristimulus values of the X₁₀Y₁₀Z₁₀ colorimetric system (JIS Z8701 1999) of X₁₀=80.7, Y₁₀=85.6, Z₁₀=91.5, and the white plate had an object color of the L*a*b* colorimetric system of L*=94.14, a*=−0.90, b*=0.24) as the standard color was measured according to JIS H8730 with a colorimeter, MiniScan XE Plus, produced by Hunter Associates Laboratory, Inc. The color difference ΔL herein is the color difference that is in the case where the object color of the white plate is the standard color, and is the color difference ΔL based on JIS Z8730 (i.e., the difference in CIE luminosity L* of the two objects in the L* a* b* colorimetric system defined in JIS 28729 (2004)) . In the colorimeter, the color difference is calibrated with ΔE*ab=0 as the measured value of the color difference of the white plate, and ΔE*ab=94.14 as the measured value of the color difference measured with the measurement port covered with a black bag (light trap) . Herein, the color difference ΔE*ab is defined as 0 for the white plate and 94.14 for black color. The color difference ΔE*ab according to JIS Z8730 of a microscopic area, such as a surface of a copper circuit, can be measured with a known measurement equipment, such as a microscopic area spectrophotometer (Model: VSS 400) , produced by Nippon Denshoku Industries Co., Ltd., and a microscopic area spectrophotometer (Model: SC-50μ), produced by Suga Test Instruments Co., Ltd.

### Sz, Sa, and Sku of Surface

The surfaces of the metal materials for heat radiation on the side of the heat generating component were evaluated for Sz, Sa, and Sku in the following manner.

Sz, Sa, and Sku of the surface of the metal material for heat radiation were measured according to ISO 25178 with a laser microscope, OLS 4000 (LEXT OLS 4000) , produced by Olympus Corporation. An area of approximately 200 μm×200 μm (specifically 40,106 μm²) was measured by using an objective lens of a magnification of 50 of the laser microscope, and Sz, Sa, and Sku were calculated. In the case where the measurement surface of the measurement result became a curved surface (not a flat surface) in the measurement with the laser microscope, Sz, Sa, and Sku were calculated after performing the plane correction. The environment temperature for the measurement of Sz, Sa, and Sku with the laser microscope was from 23 to 25°C.

2. Production of Structure having Graphite for Heat Radiation and Structure having Metal Material for Heat Radiation

Subsequently, as shown in FIGS. 1 to 5, a structure having graphite for heat radiation and structures having a metal material for heat radiation were produced. In the following description, the “high thermal conductive resin A” shows a silicone oil compound for heat radiation, Model No. G-776, produced by Shin-Etsu Chemical Co., Ltd., and the “high thermal conductive resin B” shows a silicone resin, Denka Thermally Conductive Spacer, Grease Type, grade: GFC-L1, produced by Denka Co., Ltd.

A heat generator (a heat generator containing heating wire embedded in a resin, corresponding to an IC chip) having a size of length×width×height=15 mm×15 mm×1 mm was prepared, and the periphery of the heat generator was covered with a heat generator protective member having a thickness of 200 μm formed of a stainless steel. The high thermal conductive resin B was filled between the heat generator and the heat generator protective member. The thickness of the high thermal conductive resin B was 300 μm while the thickness did not affect the heat radiation test described later. The assembly of the heat generator, the heat generator protective member, and the high thermal conductive resin B was designated as the heat generating component.

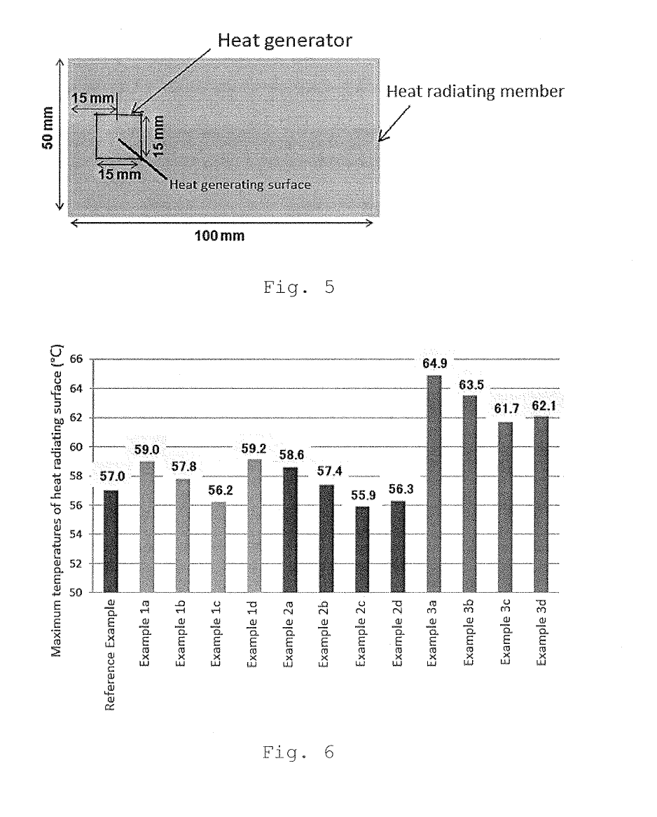

Subsequently, various heat radiating members were provided on the face of the heat generator protective member on the side opposite to the heat generator. The heat radiating member was formed to have a size of length×width×thickness =50 mm×100 mm×(total thickness of layers). FIG. 5 shows the position of the heat radiator provided with respect to the horizontal plane (length×width=50 mm×100 mm) of the heat radiating member. The heat generator was provided in such a manner that the center of the heat generator was at the center in the lengthwise direction of the heat radiating member and was distant from one edge in the crosswise direction of the heat radiating member by 15 mm.

Structure having Graphite for Heat Radiation of Reference Example

In the structure having graphite for heat radiation of Reference Example, as shown in FIG. 1, on the face of the heat generator protective member on the side opposite to the heat generator, from the side of the heat generator, the high thermal conductive resin A having a thickness of 25 μm, a double-sided adhesive tape (film) using an acrylic adhesive having a thickness of 20 μm, a graphite sheet having a thickness of 25 μm, a double-sided adhesive tape (film) using an acrylic adhesive having a thickness of 20 μm, a graphite sheet having a thickness of 25 μm, a double-sided adhesive tape (film) using an acrylic adhesive having a thickness of 20 μm, a graphite sheet having a thickness of 25 μm, and an acrylic adhesive having a thickness of 20 μm were provided as a heat radiating member, and an air layer was further provided as the outermost layer.

Structures having Metal Material for Heat Radiation of Examples 1a, 1b, and 1c

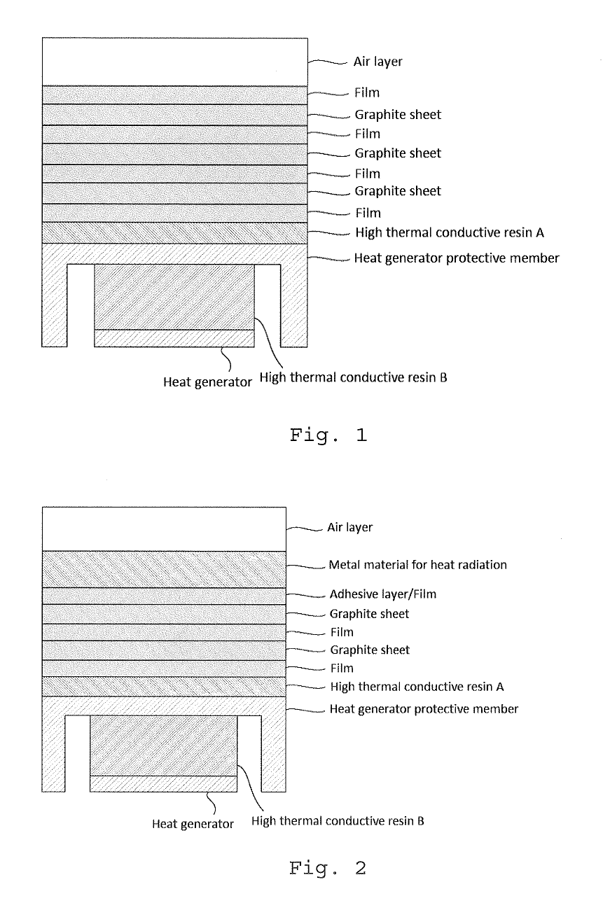

In the structures having a metal material for heat radiation of Examples 1a, 1b, and 1c, as shown in FIG. 2, on the face of the heat generator protective member on the side opposite to the heat generator, from the side of the heat generator, the high thermal conductive resin A having a thickness of 25 μm, a double-sided adhesive tape (film) using an acrylic adhesive having a thickness of 20 μm, a graphite sheet having a thickness of 25 μm, a double-sided adhesive tape (film) using an acrylic adhesive having a thickness of 20 μm, a graphite sheet having a thickness of 25 μm, a double-sided adhesive tape (adhesive layer/film) using an acrylic adhesive having a thickness of 20 μm, and the aforementioned metal material for heat radiation having a thickness of 50 μm (Example 1a), 70 μm (Example 1b), or 100 μm (Example 1c) were provided as a heat radiating member, and an air layer was further provided as the outermost layer.

Structure having Metal Material for Heat Radiation of Example 1d

In the structure having a metal material for heat radiation of, Example 1d, as shown in FIG. 2, on the face of the heat generator protective member on the side opposite to the heat generator, from the side of the heat generator, the high thermal conductive resin A having a thickness of 25 μm, a double-sided adhesive tape (film) using an acrylic adhesive having a thickness of 20 μm, a graphite sheet having a thickness of 25 μm, a double-sided adhesive tape (film) using an acrylic adhesive having a thickness of 20 μm, a graphite sheet having a thickness of 25 μm, a double-sided adhesive tape (adhesive layer/film) using an acrylic adhesive having a thickness of 20 μm, and the following metal material for heat radiation having a thickness of 100 μm (Example 1d) were provided as a heat radiating member, and an air layer was further provided as the outermost layer.

As the metal material for heat radiation of Example 1d, a copper substrate (rolled copper foil, having a composition of a tough pitch copper defined in JIS H3100, alloy number: C1100, having Ag added thereto in an amount of 200 ppm by mass, obtained by repeatedly performing rolling and annealing, and then rolling with an oil film equivalent amount of 25,000 in the final cold rolling in the production of the rolled copper foil) was used. A rust preventing layer was provided on the surface of the copper substrate. The rust preventing layer was an organic material layer formed of 1,2,3-benzotriazole, which was a triazole compound having a substituent.

Structures having Metal Material for Heat Radiation of Examples 2a, 2b, and 2c

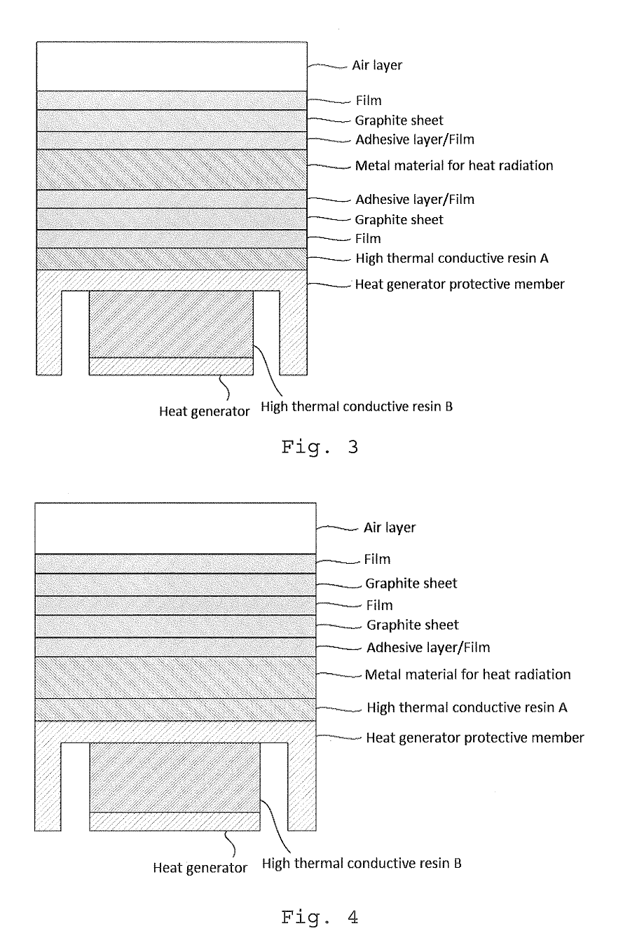

In the structures having a metal material for heat radiation of Examples 2a, 2b, and 2c, as shown in FIG. 3, on the face of the heat generator protective member on the side opposite to the heat generator, from the side of the heat generator, the high thermal conductive resin A having a thickness of 25 μm, a double-sided adhesive tape (film) using an acrylic adhesive having a thickness of 20 μm, a graphite sheet having a thickness of 25 μm, a double-sided adhesive tape (adhesive layer/film) using an acrylic adhesive having a thickness of 20 μm, the same metal material for heat radiation as used in Examples la, lb, and lc having a thickness of 50 μm (Example 2a) , 70 μm (Example 2b) , or 100 μm (Example 2c) , a double-sided adhesive tape (adhesive layer/film) using an acrylic adhesive having a thickness of 20 μm, a graphite sheet having a thickness of 25 μm, and a PET film (adhesive layer/film) having a thickness of 20 μm were provided as a heat radiating member, and an air layer was further provided as the outermost layer.

Structure having Metal Material for Heat Radiation of Example 2d

In the structure having a metal material for heat radiation of Example 2d, as shown in FIG. 3, on the face of the heat generator protective member on the side opposite to the heat generator, from the side of the heat generator, the high thermal conductive resin A having a thickness of 25 μm, a double-sided adhesive tape (film) using an acrylic adhesive having a thickness of 20 μm, a graphite sheet having a thickness of 25 μm, a double-sided adhesive tape (adhesive layer/film) using an acrylic adhesive having a thickness of 20 μm, the following metal material for heat radiation having a thickness of 100 μm (Example 2d), a double-sided adhesive tape (adhesive layer/film) using an acrylic adhesive having a thickness of 20 μm, a graphite sheet having a thickness of 25 μm, and a PET film (adhesive layer/film) having a thickness of 20 μm were provided as a heat radiating member, and an air layer was further provided as the outermost layer.

As the metal material for heat radiation of Example 2d, a copper substrate (rolled copper foil, having a composition of a tough pitch copper defined in JIS H3100, alloy number: C1100, having Ag added thereto in an amount of 200 ppm by mass, obtained by repeatedly performing rolling and annealing, and then rolling with an oil film equivalent amount of 25,000 in the final cold rolling in the production of the rolled copper foil) was used. A rust preventing layer was provided on the surface of the copper substrate. The rust preventing layer was an organic material layer formed of 1,2,3-benzotriazole, which was a triazole compound having a substituent.

Structures having Metal Material for Heat Radiation of Examples 3a, 3b, and 3c

In the structures having a metal material for heat radiation of Examples 3a, 3b, and 3c, as shown in FIG. 4, on the face of the heat generator protective member on the side opposite to the heat generator, from the side of the heat generator, the high thermal conductive resin A having a thickness of 25 μm, the same metal material for heat radiation as used in Examples la, lb, and lc having a thickness of 50 μm (Example 3a), 70 μm (Example 3b), or 100 μm (Example 3c), a double-sided adhesive tape (adhesive layer/film) using an acrylic adhesive having a thickness of 20 μm, a graphite sheet having a thickness of 25 μm, a double-sided adhesive tape (adhesive layer/film) using an acrylic adhesive having a thickness of 20 μm, a graphite sheet having a thickness of 25 μm, and a PET film (film) having a thickness of 20 μm were provided as a heat radiating member, and an air layer was further provided as the outermost layer.

Structure having Metal Material for Heat Radiation of Example 3d

In the structure having a metal material for heat radiation of Example 3d, as shown in FIG. 4, on the face of the heat generator protective member on the side opposite to the heat generator, from the side of the heat generator, the high thermal conductive resin A having a thickness of 25 μm, the following metal material for heat radiation having a thickness of 100 μm (Example 3d), a double-sided adhesive tape (adhesive layer/film) using an acrylic adhesive having a thickness of 20 μm, a graphite sheet having a thickness of 25 μm, a double-sided adhesive tape (adhesive layer/film) using an acrylic adhesive having a thickness of 20 μm, a graphite sheet having a thickness of 25 μm, and a PET film (film) having a thickness of 20 μm were provided as a heat radiating member, and an air layer was further provided as the outermost layer.

As the metal material for heat radiation of Example 3d, a copper substrate (rolled copper foil, having a composition of a tough pitch copper defined in JIS H3100, alloy number: C1100, having Ag added thereto in an amount of 200 ppm by mass, obtained by repeatedly performing rolling and annealing, and then rolling with an oil film equivalent amount of 25,000 in the final cold rolling in the production of the rolled copper foil) was used. A rust preventing layer was provided on the surface of the copper substrate. The rust preventing layer was an organic material layer formed of 1,2,3-benzotriazole, which was a triazole compound having a substituent.

### Measurement of Reflectance

The aforementioned specimens were measured for reflectances to the wavelengths of light under the following condition. The measurement was performed twice with the measurement direction changed by 90° within the measurement plane of the specimen.

Measurement equipment: IFS-66v (FT-IR with vacuum optical system, produced by Bruker Corporation)

Light source: Grover (SiC)

Detector: MCT (HgCdTe)

Beam splitter: Ge/KBr

Measurement condition: resolution: 4 cm⁻¹

Cumulated number: 512

Zero filling: twice

Apodization: triangle

Measurement range: 5,000 to 715 cm⁻¹ (light wavelength: 2 to 14 μm)

Measurement temperature: 25° C.

Auxiliary device: integrating sphere for measuring transmittance and reflectance

Port diameter: 10 mm

Repetitive accuracy: ca. ±1%

Measurement condition for reflectance:
Incident angle: 10°
Reference specimen: diffuse gold (Infragold-LF Assembly)
Specular cup (specular component removing device): not provided

### Radiation Factor

Light incident on the specimen surface is reflected and transmitted, and also is absorbed in the interior thereof. The absorbance (α) (=radiation factor (ε)), the reflectance (r), and the transmittance (t) satisfy the following expression.

ε+r+t=1 (A)

The radiation factor (ε) can be obtained from the reflectance and the transmittance according to the following expression.

ε=1−r−t (B)

In the case where the specimen is opaque, or the transmittance can be ignored due to the large thickness thereof, t=0 is established, and the radiation factor can be obtained only from the reflectance.

ε=1−r (C)

The expression (C) was applied to the specimen since the specimen did not transmit an infrared ray, and the radiation factors to the wavelengths of light were calculated.

### FT-IR Spectrum

The average value of the results of the measurement performed twice was designated as the reflectance spectrum. The reflectance spectrum was calibrated with the reflectance of diffuse gold (nominal wavelength region: 2 to 14 μm).

Assuming that the energy intensity at the wavelength λ is E_{bλ}, and the radiation factor of the specimen at the wavelength λ is ελ, the radiation energy intensity of the specimen E_{sλ} is expressed by E_{sλ}=ελ·E_{bλ}, from a radiation energy distribution of a blackbody at a certain temperature obtained by the plank's expression. In the examples, the radiation energy intensity E_{sλ}, of the specimen at 25° C. was obtained by the expression E_{sλ}=ελ·E_{bλ}.

The total energy values of a blackbody and the specimen in a certain wavelength range are obtained as the integrated values of E_{sλ} and E_{bλ} in the wavelength range, and the total radiation factor ε is expressed by the ratio thereof (expression (A) below). In the examples, the total radiation factor ε of the specimen in a wavelength range of from 2 to 14 μm at 25° C. was obtained by the expression. The total radiation factor ε thus obtained was designated as the radiation factor of the spcimen.

ε=∫_{λ=2}^{λ=14}E_{sλ}dλ/∫_{λ=2}^{λ=14}E_{bλ}dλ (A)

The structures of Reference Example and Examples 1a to 3d were subjected to heat radiation simulation under the following conditions.

Steady analysis

The flux, the laminar flow, and the gravity were considered.

Heat quantity of heat generator: 2.9 W

The lower side of the heat generator and the upper side of the heat radiating member were set as the following heat radiation conditions.

Environmental temperature: 20° C.

Surface thermal conduction coefficient: 6 W/m²·K

The wall opposite to the side receiving the radiation heat was set as a blackbody at 20° C.

The radiation in solid was not considered.

The calculation conditions and the property values are shown in Table 1.

TABLE 1

| | | | Thermal | |
|---|---|---|---|---|
| | | Specific | conduction | |
| Property of | Density | heat | coefficient | Radiation |
| material | (kg/m³) | (J/kg · K) | (W/m · K) | factor |
| Air | assumed as ideal gas | | | |
| Stainless | 7,930 | 590 | 16 | 0.1 |
| steel | | | | |
| Adhesive | 1,200 | 1,470 | 0.16 | 0.9 |
| layer/film | | | | (estimate |
| | | | | value) |
| Metal | 8,978 | 381 | 390 | 0.206 |
| material for | | | | |
| heat | | | | |
| radiation | | | | |
| Graphite | 850 | 710 | lengthwise | — |
| sheet | | | 3.5, | |
| | | | crosswise | |
| | | | 1,500 | |
| High thermal | 1,900 | 1,400 | 1 | — |
| conductive | | | | |
| resin A | | | | |
| High thermal | 3,200 | 1,470 | 1 | — |
| conductive | | | | |
| resin B | | | | |

The maximum temperatures of the outermost surfaces (heat radiation surfaces) of the heat radiating members of Reference Example and Examples, which are the results of the simulation, are shown in FIG. 6.

### Evaluation Results

All Examples 1a to 3d had the heat generator, the heat generator protective member provided to cover a part or the entire of the heat generator, and the heat radiating member disposed on the side opposite to the heat generator with respect to the heat generator protective member, in which the heat radiating member had a layer structure containing the metal material for heat radiation and the graphite sheet, and therefore were able to radiate favorably the heat from the heat generator.

Examples 2a to 2d having the metal material for heat radiation provided between the two layers of the graphite sheets were more excellent in heat radiation effect than all the other Examples, and Examples 1a to 1d having the metal material for heat radiation provided far from the heat generator with respect to the two layers of the graphite sheets were more excellent in heat radiation effect than Examples 3a to 3d having the metal material for heat radiation provided close to the heat generator with respect to the two layers of the graphite sheets.

1. A structure having a metal material for heat radiation, comprising a heat generating component and a heat radiating member for radiating heat from the heat generating component,
wherein the heat radiating member has a layer structure containing a metal material for heat radiation and a graphite sheet.

2. The structure having a metal material for heat radiation according to claim 1, wherein the heat radiating member contains the graphite sheet and the metal material for heat radiation in this order from the side of the heat generating component.

3. The structure having a metal material for heat radiation according to claim 1, wherein the heat radiating member contains the metal material for heat radiation and the graphite sheet in this order from the side of the heat generating component.

4. The structure having a metal material for heat radiation according to claim 2, wherein the heat radiating member contains a plurality of the graphite sheets.

5. The structure having a metal material for heat radiation according to claim 3, wherein the heat radiating member contains a plurality of the graphite sheets.

6. The structure having a metal material for heat radiation according to claim 1, wherein the heat radiating member contains the graphite sheet, the metal material for heat radiation, and the graphite sheet in this order from the side of the heat generating component.

7. The structure having a metal material for heat radiation according to claim 1, wherein the heat generating component is disposed to face the entire surface of the heat radiating member.

8. The structure having a metal material for heat radiation according to claim 1, wherein the heat generating component contains a heat generator and a heat generator protective member provided to cover a part or the entire of the heat generator, and
the heat radiating member is provided on the side opposite to the heat generator with respect to the heat generator protective member.

9. The structure having a metal material for heat radiation according to claim 6, wherein the structure further comprises a thermal conductive resin between the heat generator and the heat generator protective member.

10. The structure having a metal material for heat radiation according to claim 1, wherein the metal material for heat radiation contains a surface on the side of the heat generating component and/or a surface on the side opposite to the heat generating component that has a color difference ΔL based on JIS 28730 satisfying ΔL≦−40.

11. The structure having a metal material for heat radiation according to claim 1, wherein the metal material for heat radiation contains a surface on the side of the heat generating component and/or a surface on the side opposite to the heat generating component that has a radiation factor of 0.03 or more.

12. The structure having a metal material for heat radiation according to claim 1, wherein the metal material for heat radiation contains a surface treatment layer provided on a surface on the side of the heat generating component and/or a surface on the side opposite to the heat generating component, and the surface treatment layer contains one or more layers selected from the group consisting of a roughening treatment layer, a heat resistant layer, a rust preventing layer, a chromate treatment layer, a silane coupling treatment layer, a plated layer, and a resin layer.

13. The structure having a metal material for heat radiation according to claim 1, wherein the metal material for heat radiation contains copper, a copper alloy, aluminum, an aluminum alloy, iron, an iron alloy, nickel, a nickel alloy, gold, a gold alloy, silver, a silver alloy, a platinum group metal, a platinum group metal alloy, chromium, a chromium alloy, magnesium, a magnesium alloy, tungsten, a tungsten alloy, molybdenum, a molybdenum alloy, lead, a lead alloy, tantalum, a tantalum alloy, tin, a tin alloy, indium, an indium alloy, zinc, or a zinc alloy.

14. The structure having a metal material for heat radiation according to claim 13, wherein the metal material for heat radiation contains copper, a copper alloy, aluminum, an aluminum alloy, iron, an iron alloy, nickel, a nickel alloy, zinc, or a zinc alloy.

15. The structure having a metal material for heat radiation according to claim 14, wherein the metal material for heat radiation contains phosphor bronze, Corson alloy, red brass, brass, nickel silver, or other copper alloys.

16. The structure having a metal material for heat radiation according to claim 1, wherein the metal material for heat radiation is a metal strip, a metal plate, or a metal foil.

17. The structure having a metal material for heat radiation according to claim 1, wherein the metal material for heat radiation contains a surface on the side of the heat generating component and/or a surface on the side opposite to the heat generating component that has a surface roughness Sz of 5 μm or more measured with a laser microscope with laser light having a wavelength of 405 nm.

18. The structure having a metal material for heat radiation according to claim 1, wherein the metal material for heat radiation contains a surface on the side of the heat generating component and/or a surface on the side opposite to the heat generating component that has a surface roughness Sa of 0.13 μm or more measured with a laser microscope with laser light having a wavelength of 405 nm.

19. The structure having a metal material for heat radiation according to claim 1, wherein the metal material for heat radiation contains a surface on the side of the heat generating component and/or a surface on the side opposite to the heat generating component that has a surface roughness Sku of 6 or more measured with a laser microscope with laser light having a wavelength of 405 nm.

20. The structure having a metal material for heat radiation according to claim 1, wherein the heat radiating member further contains a substance having thermal conductivity provided on the side of the heat generating component.

21. The structure having a metal material for heat radiation according to claim 20, wherein the substance has a thermal conductivity of 0.5 W/(m·K) or more.

22. A printed circuit board comprising the structure having a metal material for heat radiation according to claim 1.

23. An electronic apparatus comprising the structure having a metal material for heat radiation according to claim 1.

24. A metal material for heat radiation comprising one or more surfaces, wherein at least one of the surfaces satisfies one or more of the following items (1) to (5), and the metal material for heat radiation is to be adhered with a graphite sheet and to be used as a heat radiating member:
(1) the surface having a color difference ΔL based on JIS 28730 of ΔL≦−40;
(2) the surface having a radiation factor of 0.03 or more;
(3) the surface having a surface roughness Sz of 5 μm or more measured with a laser microscope with laser light having a wavelength of 405 nm;
(4) the surface having a surface roughness Sa of 0.13 μm or more measured with a laser microscope with laser light having a wavelength of 405 nm; and
(5) the surface having a surface roughness Sku of 6 or more measured with a laser microscope with laser light having a wavelength of 405 nm.
